(19) United States
(12) Patent Application Publication
(10) Pub. No.: US 2006/0166435 A1
(43) Pub. Date: Jul. 27, 2006

(54) Synthesis of GE nanocrystal memory cell and using a block layer to control oxidation kinetics

(76) Inventors: Lee Wee Teo, Singapore (SG); Sripao Sheshagiri Nagarao, Singapore (SG); Elgin Kiok Boone Quek, Singapore (SG); Dong Kyun Sohn, Singapore (SG)

Correspondence Address: WILLIAM STOFFEL, PMB 455, 1735 MARKET ST. - STE. A, PHILADELPHIA, PA, 19103-7502, US

(21) Appl. No.: 11/040,620

(22) Filed: Jan. 21, 2005

(51) Int. Cl. H01L 21/336

(52) U.S. Cl. 438/257

(57) ABSTRACT

A structure and a method of manufacturing a memory devices using nanoncrystals. A first embodiment is characterized as follows. We form a first gate insulator over the substrate. The first gate insulator is comprised of an oxide layer and blocking layer. We form a SiGe layer over the first gate insulator layer. Then we perform an oxidation/anneal process consume the SiGe layer to form Ge nanocrystals7 on the first gate insulator layer and a silicon oxide layer over the first gate insulator layer. We form a gate electrode over the a silicon oxide layer. In a second embodiment, the first gate insulator is comprised of one layer of oxidation blocking material. The blocking layer prevents the oxidation of the substrate during process steps used to form the nanocrystals.

### BACKGROUND OF THE INVENTION

1) Field of the Invention

The present invention relates generally to Flash memory devices and more particularly to Flash memory devices using nanoncrystals.

2) Description of the Prior Art

The increasing use of portable electronics and embedded systems has resulted in a need for low-power high-density non-volatile memories that can be programmed at very high speeds. One type of memory, which has been developed, is Flash electrically erasable programmable read only memory (Flash EEPROM). It is used in many portable electronic products, such as personal computers, cell phones, portable computers, voice recorders, etc. as well as in many larger electronic systems, such as cars, planes, industrial control systems, etc.

A Flash EEPROM device is formed on a semiconductor substrate. In portions of the surface of the substrate, a doped source region and a doped drain region are formed with a channel region therebetween. A tunnel silicon oxide dielectric layer is formed on the semiconductor substrate over the channel region and between the source and drain regions. Above the tunnel silicon oxide dielectric layer, over the channel region, a stacked-gate structure is formed for a transistor having a floating gate layer, an inter-electrode dielectric layer, and a control gate layer. The source region is located on one side of the stacked gate structure with one edge of the source region overlapping the gate structure. The drain region is located on the other side of the stacked gate structure with one edge overlapping the gate structure. The device is programmed by hot electron injection and erased by Fowler-Nordheim tunnelling.

A silicon (Si) nanocrystal Flash EEPROM device has been proposed that can be programmed at fast speeds (hundreds of nanoseconds) using low voltages for direct tunneling and storage of electrons in the silicon nanocrystals. By using nanocrystal charge storage sites that are isolated electrically, charge leakage through localized defects in the gate oxide layer is presumably reduced.

There is the extensive technological development directed to the subject, as documented by the relevant patent and technical literature. The more relevant technical developments in the patent literature can be gleaned by considering the following patents.

U.S. Pat. No. 6,656,792 Choi, et al.—Nanocrystal flash memory device and manufacturing method therefor—A Flash memory is provided having a trilayer structure of rapid thermal oxide/germanium (Ge) nanocrystals in silicon dioxide (SiO2)/sputtered SiO2 cap with demonstrated via capacitance versus voltage (C-V) measurements having memory hysteresis due to Ge nanocrystals in the middle layer of the trilayer structure. The Ge nanocrystals are synthesized by rapid thermal annealing of a co-sputtered Ge+SiO₂ layer.

U.S. Pat. No. 6,413,819 Zafar, et al. Jul. 2, 2002 Memory device and method for using prefabricated isolated storage elements—shows a process to form floating gates with nanocrystals.

U.S. Pat. No. 6,699,754 Huang Mar. 2, 2004—Flash memory cell and method for fabricating the same—includes a method of fabricating a flash memory cell. First, a polysilicon layer and a germanium layer are successively formed over a substrate and insulated from the substrate. Subsequently, the substrate is annealed to form a germanium layer having a plurality of hut structures on the polysilicon layer to serve as a floating gate with the polysilicon layer. Next, a control gate is formed over the floating gate and insulated from the floating gate.

U.S. Pat. No. 6,090,666 Ueda, et al. Jul. 18, 2000 Method for fabricating semiconductor nanocrystal and semiconductor memory device using the semiconductor nanocrystal—Under a low pressure below atmospheric pressure, an amorphous silicon thin film 3 is deposited on a tunnel insulating film 2 formed on a silicon substrate 1. After the deposition of the amorphous silicon thin film 3, the amorphous silicon thin film 3 is heat treated at a temperature not lower than the deposition temperature of the amorphous silicon thin film 3 in an atmosphere of helium gas having no oxidizability, by which a plurality of spherical nanocrystals 4 with a diameter of 18 nm or less are formed on the tunnel insulating film 2 so as to be spaced from one another. The plurality of nanocrystals 4 are used as the floating gate of a semiconductor memory device.

United States Patent Application 20040130941 A1—Kan, Edwin C.; et al. Jul. 8, 2004 Multibit metal nanocrystal memories and fabrication—Metal nanocrystal memories are fabricated to include higher density states, stronger coupling with the channel, and better size scalability, than has been available with semiconductor nanocrystal devices. A self-assembled nanocrystal formation process by rapid thermal annealing of ultra thin metal film deposited on top of gate oxide is integrated with NMOSFET to fabricate such devices.

### SUMMARY OF THE INVENTION

The embodiments of the present invention provides a structure and a method of manufacturing a memory devices using nanoncrystals.

A first example method embodiment is characterized as follows.
We form a first gate insulator over the substrate. The first gate insulator is comprised of an oxide layer and blocking layer.
We form a SiGe layer over the first gate insulator layer.
Then we perform an oxidation/anneal process consume the SiGe layer to form Ge nanocrystals on the first gate insulator layer and a silicon oxide layer over the first gate insulator layer.
We form a gate electrode over the a silicon oxide layer and define a channel region in the substrate under the gate electrode.
We form a source and a drain region in the substrate and adjacent to the channel region.

In a second embodiment, the first gate insulator is comprised of one layer of oxidation blocking material. The blocking layer prevents the oxidation of the substrate during process steps used to form the nanocrystals.

An example structure embodiment comprises:
a first gate insulator over a substrate; the first gate insulator is comprised of a material that substantially blocks the oxidation of the substrate;
Ge nanocrystals over the first gate insulator layer and a silicon oxide layer over the first gate insulator layer and the Ge nanocrystals;
a gate electrode over the a silicon oxide layer and defining a channel region in the substrate under the gate electrode;
a source and a drain region in the substrate and adjacent to the channel region.

In an aspect, the first gate insulator is comprised of a dielectric layer and blocking layer; the blocking layer is comprised of a material that substantially prevents the oxidation of the substrate;

In another aspect, the first gate insulator is substantially of comprised of silicon nitride or silicon oxynitride.

The above and below advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1A through 1E are cross sectional views for illustrating a method for manufacturing a memory device according to an example embodiment of the present invention.

FIGS. 2A through 2D and 1E are cross sectional views for illustrating a method for manufacturing a memory device according to an example embodiment of the present invention.

### DETAILED DESCRIPTION OF THE EXAMPLE EMBODIMENTS

A. Introduction

Example embodiments of the invention form a nanocrystals memory device having a gate insulating layer that acts as an oxidation blocker. The gate insulating layer substantially blocks the oxidization of the substrate during subsequent oxidation step such as oxidation steps using to form the nanocrystals. The gate insulating layer preferably acts as a tunneling layer.

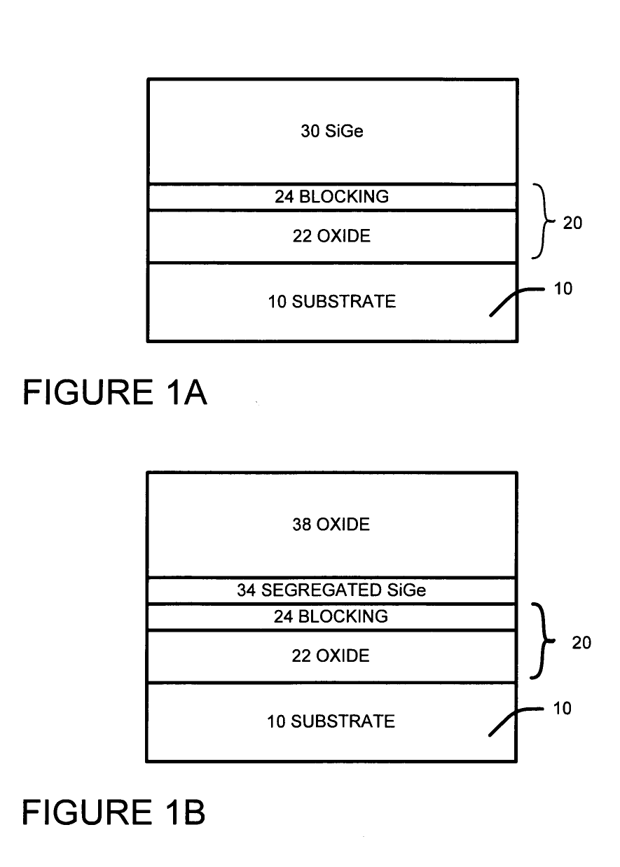

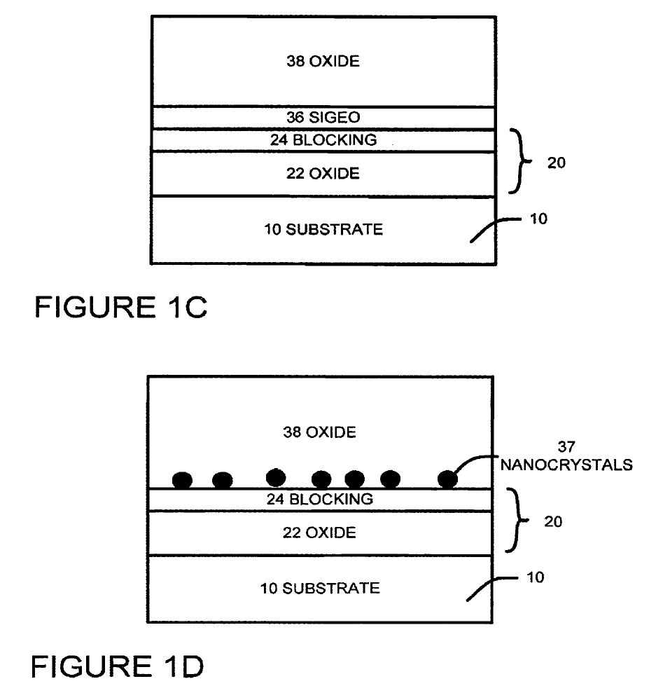

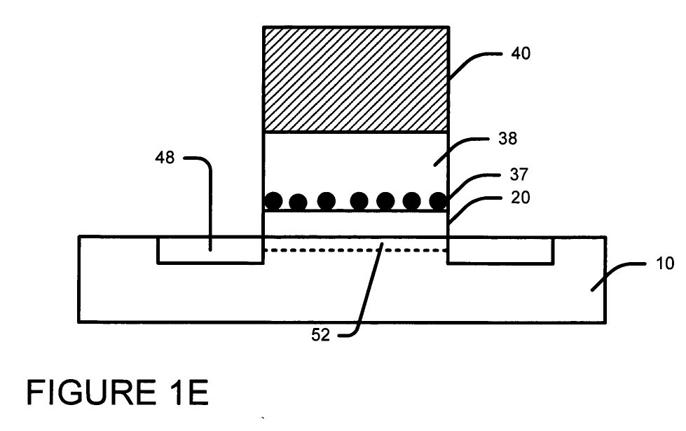

In a first example embodiment, a nanocrystal memory device is formed where the gate insulating layer is comprised of a lower dielectric layer and an upper oxidation blocking layer. See e.g., FIG. 1D, gate insulating layer comprised of blocking layer 24 over lower dielectric layer 22 over the substrate 10. The blocking layer 24 prevents the oxidation of the substrate during process steps used to form the nanocrystals 37.

In a second example embodiment, the gate insulting layer is comprised of one blocking layer comprised preferably of silicon nitride or DPN oxide, high k dielectric (HfO2).

II. First Example Embodiment—FIGS. 1A to 1E

A first example embodiment, a nanocrystal memory device is formed where the gate insulating layer is comprised of a dielectric layer (e.g., SiO2, high-k dielectric) and an upper oxidation blocking layer. See e.g., FIG. 1d, gate insulating layer 20 comprised of blocking layer 24 over dielectric layer 22 over the substrate 10. The blocking layer 24 prevents the oxidation of the substrate during process steps used to form the nanocrystals 37.

A. Form gate insulating layer

Referring to FIG. 1A, we form a gate insulating layer 20 over a substrate.

The substrate can be a silicon wafer or any feasible semiconductor substrate. The substrate can be comprised of silicon (Si), strained-Si, germanium (Ge), strained Ge, gallium arsenide (GaAs), silicon-germanium (SiGe), silicon-on-insulator (SOI), or semiconductor layer-on-substrate materials.

The blocking layer 24 prevents the oxidation of the substrate during process steps used to form the nanocrystals 37.

The gate insulating layer 20 comprised of blocking layer 24 over dielectric layer 22 over the substrate 10. The blocking layer 24 prevents the oxidation of the substrate during process steps used to form the nanocrystals 37.

In the first aspect, the first gate insulator 20 is comprised of a dielectric layer 22 and blocking layer 24.

Dielectric Layer

The dielectric layer 22 is preferably an oxide layer preferably has a thickness between 30 and 60 Å. The oxide layer is preferably formed by a thermal process (dry or wet) or rapid thermal oxidation (wet or dry) or LPCVD high temp oxide (HTO). The oxide layer is a tunneling oxide layer. The blocking layer 24 can be comprised of a high k material (dielectric K equal to or great than 3.0), for example HfO₂ (EOT ˜20 to 60 A), Al₂O₃ or ZrO₂ or TiO₂ (with similar EOT).

Blocking Layer 24

The blocking layer 24 is comprised of a material that can substantially block the oxidation of the substrate in subsequent steps.

Preferably the blocking layer is essentially comprised of silicon nitride and preferably has a thickness between 5 and 10 angstroms.

Also, the blocking layer 24 can be silicon oxynitride. The Also, the blocking layer 24 can be silicon oxynitride. with a N conc between 5 and 15% and can have a thickness between 5 and 25 Å.

The blocking layer can be formed 1) forming a silicon oxide layer and 2) followed by a decoupled plasma nitridation (DPN) with nitrogen conc 5% to 20% to create a SiON blocking layer. The blocking layer 24 can be comprised of a high k material, for example HfO2 (EOT ˜20 to 60 A).

The blocking layer is also a tunneling layer or can be completely consumed during the oxidation.

B. form a silicon germanium (SiGe) layer

Referring to FIG. 1B, we form a SiGe layer 38 over the first gate insulator layer 20. The SiGe layer preferably has a thickness between 60 and 120 Å.

The SiGe layer can be comprised of poly SiGe, or amorphous SiGe.

C. perform an oxidation/anneal process consume the SiGe layer to form Ge nanocrystals

Next, we perform an oxidation process and an anneal process consume the SiGe layer 30 to form Ge nanocrystals 37 on the first gate insulator layer 20 and a silicon oxide layer 38 over the first gate insulator layer 20.

In an example embodiment, the oxidation/anneal process comprises:

1) a high temperature dry oxidation;

2) a low temperature wet oxidation process and

3) an anneal.

This is described below. See FIGS. 1B thru 1D.

(1) High Temperature Dry Oxidation

Referring to FIGS. 1B, a high temperature 900 C) dry oxidation is performed to convert the SiGe layer 30 into a segregated SiGe layer 36 (Si_{1-y}Ge_{y} (y>x) and a silicon oxide layer 38. The segregated SiGe layer 36 (Si_{1-y}Ge_{y} (y>x) is located over the first gate insulator 20. The segregated SiGe layer 36 (Si_{1-y}Ge_{y} (y>x) can also be called the Ge nanocrystal formation layer or middle layer.

The high temperature (e.g., 900 C) dry oxidation preferably has the following parameters ranges;

Temperature between 800 and 1000 C;

Time between 5 min and 30 min;

Flow only O₂ (no H₂O) or N₂O or NO;

High temperature dry oxidation can be done by furnace oxidation or by rapid thermal oxidation.

(2) A Low Temperature Wet Oxidation Process

Referring to FIG. 1C, we perform a low temperature (e.g., 650 C) wet oxidation process that converts the segregated SiGe layer 36 (Si_{1-y}Ge_{y} (y>x) into a SiGeO layer 36 (Si_{1-y}Ge_{y}O₂) preferably having a thickness between 30 and 50 Å.

The low temperature dry oxidation preferably has the following parameters ranges;

Temperature between 600 and 750 C;

Time between 1 min and 15 min;

Flow H₂O gasses.

(3) An Anneal

Referring to FIG. 1D, a high temperature anneal to converts the (SiGeO) silicon germanium oxide layer 36 (Si_{1-y}Ge_{y}O₂) into Ge nanocrystals 37 over the first gate insulator 20.

The high temperature anneal preferably has the following parameters ranges;

Temperature between 950 and 1050 C;

Time between 30 sand 10 minutes;

Flow gasses N2 or inert ambient (e.g., Ar)

Annealing preferably done using rapid thermal annealing machine.

Referring to FIG. 1D, the nano crystals 37 can be positioned on or over the SiN layer 20. The nanocrystals can be just above layer 20 or above layer 24. The nanocrystals will eventually be situated at the bottom of layer 38.

D. Device

Lastly, referring to FIG. 1E, we form a gate electrode 40 over the a silicon oxide layer 38. A channel region 52 is defined in the substrate under the gate electrode.

We form a source and a drain region 48 in the substrate 10 and adjacent to the channel region 52.

This structure is a flash EEPROM transistor device. The isolated Ge nanocrystals can serve as discrete charge storage nodes that enable multibit flash memory operation.

III. Second Example Embodiment—The First Gate Insulator is a Blocking Layer

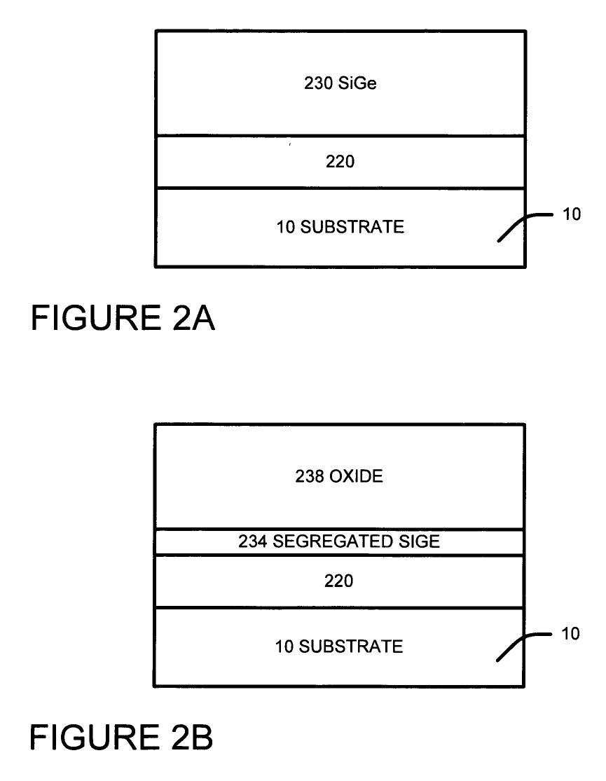

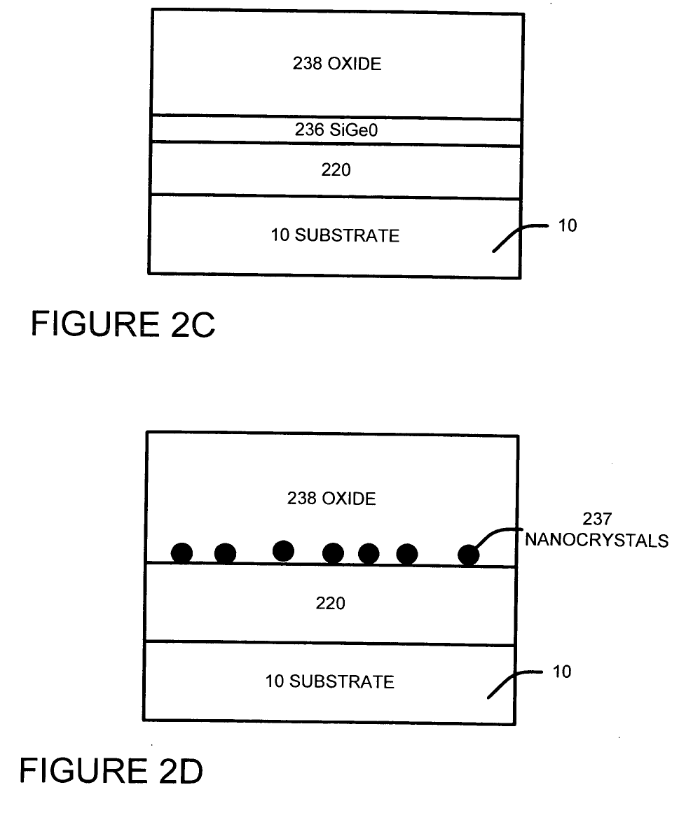

A second example embodiment is shown in FIGS. 2A through 2D. In the second example embodiment, the first gate insulator 220 is preferably comprised one layer of blocking material such as silicon nitride or SiON. The first gate insulator 220 comprised of SiON can have a nitrogen conc between about 5% and 15%.

The process steps are similar to those describe above unless noted or obvious.

Referring to FIG. 2A, we form a gate insulating layer 220 over a substrate 10.

The substrate can be a silicon wafer or any feasible semiconductor substrate.

The gate insulating layer 220 is preferably comprised of one layer of material that block the subsequent oxidation of the substrate. The gate insulating layer 220 is comprised of a blocking layer prevents the oxidation of the substrate during process steps used to form the nanocrystals 237.

In a preferred aspect, the first gate insulator 220 is comprised of a comprised of silicon nitride. The SiN can be formed by a jet vapor deposition (JVD) technique. The JVD process utilizes a high-speed jet of light carrier gas to transport the depositing species onto the substrate to form the desired films.

The first gate insulator preferably has a thickness between 60 and 100 Å.

The first gate insulator 220 is comprised of a material that can act as a tunneling layer for the memory device and as a oxidation blocking layer. The first gate insulator layer 220 could be formed of one or more layers of materials that can acts a both a tunneling layer for the memory device and as a oxidation blocking layer.

Referring to FIG. 2B, we form a SiGe layer 238 over the first gate insulator layer 20. The SiGe layer preferably has a thickness between 60 and 120 Å.

Next, we perform an oxidation/anneal process consume the SiGe layer 230 to form Ge nanocrystals 237 on the first gate insulator layer 220 and a silicon oxide layer 238 over the first gate insulator layer 220. The oxidation/anneal process can be performed as describe in the first embodiment.

Referring to FIGS. 2B, a high temperature (900 C) dry oxidation is performed to convert the SiGe layer 230 into a segregated SiGe layer 236 (Si_{1-y}Ge_{y} (y>x) and a and a silicon oxide layer 238. The segregated SiGe layer 236 (Si_{1-y}Ge_{y} (y>x) is located over the first gate insulator 220.

Referring to FIG. 2C, we perform a low temperature (650C) wet oxidation process that converts the segregated SiGe layer 236 (Si_{1-y}Ge_{y} (y>x) into a SiGeO layer 236 (Si_{1-y}Ge_{y}O₂) preferably having a thickness between 30 and 50 Å.

Referring to FIG. 2D, a high temperature anneal to converts the SiGeO layer 236 (Si_{1-y}Ge_{y}O₂) into Ge nanocrystals 237 over the first gate insulator 220.

The process continues to as we form a gate electrode over the a silicon oxide layer and source & drain regions. See for example FIG. 1E. Corresponding elements are the same for the first and second embodiments. For example, the first gate insulating layer 220 is represented by layer 20 in FIG. 1E. The nanocrystals 237 are represented by nanocrystals 37 in FIG. 1E.

IV. Memory Device Structure

An example embodiment of the invention is a memory device structure as shown in FIG. 1E and described above in the aspects of the first and second embodiments.

FIG. 1D showssA memory device, comprising:
a first gate insulator over a substrate; said first gate insulator is comprised of a material that substantially blocks the oxidation of said substrate;
Ge nanocrystals over said first gate insulator layer and a silicon oxide layer over said first gate insulator layer and said Ge nanocrystals;
a gate electrode over said a silicon oxide layer and defining a channel region in said substrate under said gate electrode;
a source and a drain region in the substrate and adjacent to the channel region.

A. Overview

The insertion of a thin nitride layer between the tunneling oxide and the SiGe layer aims at a better control of the oxidation kinetics of the gate stack. The thin nitride film serves as an oxidation barrier during the sequential oxidation of the SiGe layer and accurately stopping the oxidation process at the intended thickness. Some advantages are: (1) An accurate and easy control of tunneling oxide layer thickness which is critical for uniform programming characteristics, (2) The absence of Ge using this invention at the channel interface which degrades transistor performance.

B. non-limiting embodiment

In the above description numerous specific details are set forth such as flow rates, pressure settings, thicknesses, etc., in order to provide a more thorough understanding of the present invention. Those skilled in the art will realize that power settings, residence times, gas flow rates are equipment specific and will vary from one brand of equipment to another. It will be obvious, however, to one skilled in the art that the present invention may be practiced without these details. In other instances, well known process have not been described in detail in order to not unnecessarily obscure the present invention.

Unless explicitly stated otherwise, each numerical value and range should be interpreted as being approximate as if the word about or approximately preceded the value of the value or range.

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

1. A method of making a memory device, comprising the steps of:
a) providing a substrate;
b) forming a first gate insulator over said substrate; said first gate insulator is comprised of a material that substantially blocks the oxidation of said substrate;
c) forming a SiGe layer over said first gate insulator layer;
d) performing an oxidation/anneal process consume said SiGe layer to form Ge nanocrystals over said first gate insulator layer and a silicon oxide layer over said first gate insulator layer and said Ge nanocrystals.

2. The method of claim 1 wherein the oxidation/anneal process comprises:
(1) a high temperature dry oxidation, to convert said SiGe layer into a segregated SiGe layer and a silicon oxide layer;
said segregated SiGe layer is located over said first gate insulator; and then
(2) a low temperature wet oxidation process that converts said segregated SiGe layer into a SiGeO layer;
(3) a high temperature anneal to convert said SiGeO layer into Ge nanocrystals over said first gate insulator.

3. The method of claim 1 wherein said first gate insulator is comprised of an dielectric layer and blocking layer; said blocking layer is comprised of a material that substantially prevents the oxidation of said substrate.

4. The method of claim 1 wherein said first gate insulator is comprised of an dielectric layer and a blocking layer;
said dielectric layer is comprised of a material selected from the group consisting of silicon oxide, a dielectric material with a dielectric constant equal to or greater than 3.0; HfO₂, Al₂O₃, ZrO₂ and TiO₂;
said blocking layer is comprised of a material that substantially prevents the oxidation of said substrate; said blocking layer is comprised of silicon nitride or silicon oxynitride.

5. The method of claim 1 wherein said first gate insulator is comprised of an dielectric layer and blocking layer;
said dielectric layer is comprised of oxide having a thickness between 30 and 60 Å;
said blocking layer is comprised essentially of silicon nitride and has a thickness between 5 and 10 angstroms.

6. The method of claim 1 wherein said first gate insulator is comprised of an dielectric layer and blocking layer;
said dielectric layer is comprised of silicon oxide, a dielectric material with a dielectric constant greater than 3.0; or HfO2;
said blocking layer is comprised of silicon oxynitride with a nitrogen atomic concentration between 5 to 15% and a thickness between 5 and 25 Å.

7. The method of claim 1 wherein said first gate insulator is comprised of a comprised of silicon nitride or silicon oxynitride.

8. The method of claim 1 wherein said first gate insulator is comprised of a comprised of silicon nitride or silicon oxynitride with a N atomic concentration between 5 and 15%; and has a thickness between 60 and 100 Å.

9. A method of making a memory device, comprising the steps of:
a) providing a substrate;
b) forming a first gate insulator over said substrate; said first gate insulator is comprised of a material that substantially blocks the oxidation of said substrate;
c) forming a SiGe layer over said first gate insulator layer;
d) performing an oxidation/anneal process consume said SiGe layer to form Ge nanocrystals on said first gate insulator layer and a silicon oxide layer over said first gate insulator layer;
(1) the oxidation/anneal process comprises:
(a) a high temperature dry oxidation at a temperature between 800 and 1000 C to convert said SiGe layer into a segregated SiGe layer and a silicon oxide layer;
said segregated SiGe layer is located over said first gate insulator; and then
b) a low temperature wet oxidation process at a temperature between 600 and 750 degrees C. that converts said segregated SiGe layer into a SiGeO layer;
(c) a high temperature anneal to convert said SiGeO layer into Ge nanocrystals over said first gate insulator; said silicon oxide layer over said Ge nanocrystals and said first gate insulator; said high temperature anneal at a temperature between 950 and 1050 degree C.;
e) forming a gate electrode over said silicon oxide layer and defining a channel region in said substrate under said gate electrode;
f) forming a source and a drain region in the substrate and adjacent to the channel region.

10. The method of claim 9 wherein said first gate insulator is comprised of an dielectric layer and blocking layer; said blocking layer is comprised of a material that substantially prevents the oxidation of said substrate.

11. The method of claim 9 wherein said first gate insulator is comprised of an dielectric layer and blocking layer;
said dielectric layer is comprised of a material selected from the group consisting of silicon oxide, a dielectric material with a dielectric constant equal to or greater than 3.0; or HfO₂, Al₂O₃ or ZrO₂ or TiO₂;
said blocking layer is comprised of a material that substantially prevents the oxidation of said substrate; said blocking layer is comprised of silicon nitride or silicon oxynitride.

12. The method of claim 9 wherein said first gate insulator is comprised of an dielectric layer and blocking layer;
said dielectric layer is comprised of oxide having a thickness between 30 and 60 Å;
said blocking layer is comprised essentially of silicon nitride and has a thickness between 5 and 10 angstroms.

13. The method of claim 9 wherein said first gate insulator is comprised of an dielectric layer and blocking layer;
said dielectric layer is comprised of silicon oxide, a dielectric material with a dielectric constant greater than 3.0; or HfO₂;
said blocking layer is comprised of silicon oxynitride with a nitrogen atomic concentration between 5 to 15% and a thickness between 5 and 25 Å.

14. The method of claim 9 wherein said first gate insulator is comprised of silicon nitride or silicon oxynitride.

15. The method of claim 9 wherein said first gate insulator is comprised of a comprised of silicon nitride or silicon oxynitride with a N atomic concentration between 5 and 15%; and has a thickness between 60 and 100 Å.

16. A memory device, comprising:
a) a first gate insulator over a substrate; said first gate insulator is comprised of a material that substantially blocks the oxidation of said substrate;
b) Ge nanocrystals over said first gate insulator layer and a silicon oxide layer over said first gate insulator layer and said Ge nanocrystals.

17. The memory device of claim 16 wherein said first gate insulator is comprised of a dielectric layer and blocking layer; said blocking layer is comprised of a material that substantially prevents the oxidation of said substrate.

18. The memory device of claim 16 wherein said first gate insulator is comprised of an dielectric layer and blocking layer;
said dielectric layer is comprised of a material selected from the group consisting of silicon oxide, a dielectric material with a dielectric constant equal to or greater than 3.0; or HfO₂, Al₂O₃ or ZrO₂ or TiO₂;
said blocking layer is comprised of a material that substantially prevents the oxidation of said substrate; said blocking layer is comprised of silicon nitride or silicon oxynitride.

19. The memory device of claim 16 wherein said first gate insulator is comprised of an dielectric layer and blocking layer;
said dielectric layer is comprised of oxide having a thickness between 30 and 60 Å;
said blocking layer is comprised essentially of silicon nitride and has a thickness between 5 and 10 angstroms.

20. The memory device of claim 16 wherein said first gate insulator is comprised of an dielectric layer and blocking layer;
said dielectric layer is comprised of silicon oxide, a dielectric material with a dielectric constant greater than 3.0; or HfO2;
said blocking layer is comprised of silicon oxynitride with a nitrogen atomic concentration between 5 to 15% and a thickness between 5 and 25 Å.

21. The memory device of claim 16 wherein said first gate insulator is substantially of comprised of silicon nitride or silicon oxynitride.

22. The memory device of claim 16 which further includes:
a gate electrode over said a silicon oxide layer and defining a channel region in said substrate under said gate electrode;
a source region and a drain region in the substrate and adjacent to the channel region.

23. The method of claim 1 which further includes:
forming a gate electrode over said silicon oxide layer and defining a channel region in said substrate under said gate electrode;
forming a source region and a drain region in the substrate adjacent to the channel region to form said memory device.
